(19) United States
(12) Patent Application Publication
(10) Pub. No.: US 2015/0050479 A1
(43) Pub. Date: Feb. 19, 2015

(54) GAS BARRIER FILM

(71) Applicant: FUJIFILM Corporation, Tokyo (JP)

(72) Inventors: Seigo NAKAMURA, Kanagawa (JP); Shinya SUZUKI, Kanagawa (JP)

(73) Assignee: FUJIFILM CORPORATION, Tokyo (JP)

(21) Appl. No.: 14/498,268

(22) Filed: Sep. 26, 2014

Related U.S. Application Data
(63) Continuation of application No. PCT/JP2013/055382, filed on Feb. 28, 2013.

(30) Foreign Application Priority Data
Mar. 29, 2012 (JP) 2012-075674

(51) Int. Cl. C23C 16/34; C23C 16/40

(52) U.S. Cl. CPC C23C 16/345; C23C 16/401
USPC 428/216; 428/213; 427/255.29; 427/255.394

(57) ABSTRACT

The present invention provides, as gas barrier film having improved adhesiveness between a base material and a barrier laminate, a gas barrier film including a plastic film, an organic layer and an inorganic layer in this order, the gas barrier film having a silicon compound layer including one or more compounds selected from the group consisting of silicon oxide, silicon nitride and silicon carbide between the plastic film and the organic layer; the plastic film and the silicon compound layer, and the silicon compound layer and the organic layer being directly in contact to each other respectively; the thickness of the silicon compound layer being 40 nm or less; the organic layer being a layer formed of a composition containing a polymerizable compound and a silane coupling agent; and the thickness of the inorganic layer being larger than the thickness of the silicon compound layer.

### CROSS-REFERENCE TO RELATED APPLICATIONS

This application is a continuation of PCT/JP2013/055382, which claims priority to Japanese Patent Application No. 2012-075674 filed on Mar. 29, 2012, the entire contents of which are incorporated herein by reference.

### TECHNICAL FIELD

The present invention relates to a gas barrier film. The present invention also relates to a method for manufacturing a gas barrier film.

### BACKGROUND ART

As a gas barrier film having a function of blocking water moisture, oxygen or the like, the development of a gas barrier film having a barrier laminate, in which an organic layer and an inorganic layer are laminated on a plastic film as a base material, has proceeded from various viewpoints as a film having high barrier properties. For example, in relation to a problem in which the organic layer and the inorganic layer are easily peeled apart from each other by mechanical stress in the above configuration, in Patent Literature 1, a polymer constituting the organic layer is studied. In addition, in Patent Literature 2 and Patent Literature 3, the improvement in adhesiveness between the organic layer and inorganic layer by adding a silane coupling agent and a polymerizable acidic compound to a polymerizable composition for forming the organic layer is disclosed.

### CITATION LIST

### Patent Literature

[Patent Literature 1] Japanese Patent Application Laid-Open No. 2008-221830

[Patent Literature 2] Japanese Patent Application Laid-Open No. 2011-201064

[Patent Literature 3] Japanese Patent Application Laid-Open No. 2010-200780

### SUMMARY OF INVENTION

An object of the present invention is to provide a gas barrier film having improved adhesiveness between a base material and a barrier laminate in a gas barrier film having the barrier laminate having an organic layer and an inorganic layer on a plastic film as the base material. An object of the present invention is, in particular, to provide a gas barrier film having improved adhesiveness between the plastic film and the organic layer, when using a barrier laminate having the organic layer on the plastic film side in the barrier laminate.

The present inventors have intensively studied in order to achieve the object, and have found that the adhesiveness between a base material and a barrier laminate was able to be improved by providing, on a plastic film, an inorganic-based thin film for improving the adhesiveness between the plastic film and an organic layer when forming the barrier laminate on the plastic film, and thus have completed the present invention.

That is, the present invention provides (1)-(9) below.

(1) A gas barrier film including a plastic film, an organic layer and an inorganic layer in this order, the gas barrier film having a silicon compound layer containing one or more compounds selected from the group consisting of silicon oxide, silicon nitride and silicon carbide between the plastic film and the organic layer; the plastic film and the silicon compound layer, and the silicon compound layer and the organic layer being in adjacent to each other respectively; the thickness of the silicon compound layer being 40 nm or less; and the organic layer being a layer formed of a composition containing a polymerizable compound and a silane coupling agent.

(2) The gas barrier film according to (1), wherein the thickness of the silicon compound layer is 20 nm or less.

(3) The gas barrier film according to (1), wherein the thickness of the silicon compound layer is less than 5 nm.

(4) The gas barrier film according to any one of (1) to (3), wherein the thickness of the inorganic layer is 20 nm or more.

(5) The gas barrier film according to any one of (1) to (4), wherein the silane coupling agent is a compound represented by general formula (1):

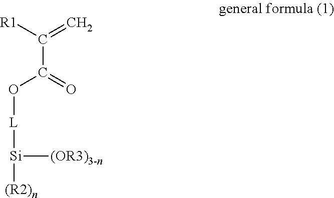

in the formula, R1 each independently represents hydrogen atom or methyl group, R2 represents a halogen atom or an alkyl group, R3 represents hydrogen atom or an alkyl group, L represents a divalent linking group, and n represents any integer of 0 to 2.

(6) The gas barrier film according to any one of (1)-(5), wherein the polymerizable compound is (meth)acrylate.

(7) The gas barrier film according to any one of (1)-(6), wherein the silicon compound layer is a layer produced by a vapor deposition method.

(8) The gas barrier film according to any one of (1)-(7), wherein the inorganic layer is a layer produced by a vapor deposition method.

(9) A method of manufacturing a gas barrier film, the method including forming an organic layer by applying and curing a composition containing a polymerizable compound onto a plastic film and forming an inorganic layer on the organic layer,

wherein a silicon compound layer containing one or more compounds selected from the group consisting of silicon oxide, silicon nitride and silicon carbide is formed at a thickness of 40 nm or less by a vapor deposition method, on a surface of the plastic film to which the composition is applied,

the composition contains a silane coupling agent, and

the composition is applied directly onto the silicon compound layer.

### Effect of the Invention

A gas barrier film having improved adhesiveness between a base material and a barrier laminate is provided by the present invention.

### MODES OF CARRYING OUT INVENTION

Hereinafter, the content of the present invention will be explained in detail.

In the present description, “to” is used in the sense that numerical values described before and after thereof are included as the value of lower limit and the value of upper limit. An “organic EL element” in the present invention denotes an organic electroluminescence element. In the description, (meth)acrylate is used in the sense of including both acrylate and methacrylate.

The gas barrier film of the present invention has a configuration including a plastic film and a barrier laminate. The gas barrier film of the present invention has a silicon compound layer between the plastic film and the barrier laminate.

The gas barrier film of the present invention may have a configuration in which the barrier laminate is provided on one surface of the plastic film, or may have a configuration in which the barrier laminate is provided on each surface of the plastic film.

### (Barrier Laminate)

The barrier laminate is a laminate having at least one organic layer and at least one inorganic layer, or may also be a laminate having two or more organic layers and two or more inorganic layers laminated alternately.

The barrier laminate may include a so-called gradient material layer in which a continuous change of an organic region and an inorganic region in the composition constituting the barrier laminate in the thickness direction is generated, within the range not departing from the gist of the present invention. Examples of the gradient materials include a material described in Journal of Vacuum Science and Technology A Vol. 23 p 971-977 (2005 American Vacuum Society) by Kim et. al., a continuous layer in which an organic region and an inorganic region has no interface as disclosed in US Published Application No. 2004-46497 and the like. Hereinafter, for simplification, the organic layer and organic region are described as an “organic layer,” and the inorganic layer and inorganic region are described as an “inorganic layer.”

The number of layers constituting the barrier laminate is not particularly limited, and, typically, 2 layers to 30 layers are preferable, and 3 layers to 20 layers are more preferable. In addition, a functional layer other than the organic layer and inorganic layer may be included.

In the gas barrier film of the present invention, the outermost surface of the barrier laminate on the plastic film side is the organic layer (hereinafter, the organic layer of the outermost surface on the plastic film side may be referred to as a “first organic layer”). That is, the gas barrier film of the present invention has the silicon compound layer between the plastic film and the first organic layer. In addition, in the gas barrier film of the present invention, the plastic film and the silicon compound layer are adjacent to each other, and the silicon compound layer and the organic layer are adjacent to each other.

### (Silicon Compound Layer)

The silicon compound layer has a function of improving the adhesiveness between the plastic film and the barrier laminate. The silicon compound layer contains a silicon compound selected from the group consisting of silicon oxide, silicon nitride and silicon carbide. The silicon compound is preferably silicon oxide or silicon nitride. The silicon compound layer may lack a function as a barrier film, may be a layer containing the same compound as that in the inorganic layer in the barrier laminate, or may be a layer containing a different compound. In the present description, the silicon compound layer and the inorganic layer in the barrier laminate is described in distinction from each other.

The silicon compound layer can exert the function of improving the adhesiveness between the plastic film and the organic layer when the compound is made into a thin film of 40 nm or less. The thickness of the silicon compound layer is preferably 20 nm or less, more preferably 10 nm or less, and particularly preferably less than 5 nm. Further, the thickness of the silicon compound layer is preferably 1 nm or more, but may be smaller than 1 nm.

As to a method for forming the silicon compound layer, any method can be used as long as it is a method that is capable of forming an intended thin film. Examples of the methods include physical vapor deposition (gas phase growth) methods (PVD) such as an evaporation method, a sputtering method and an ion plating method, various chemical vapor deposition methods (CVD), and liquid-phase growth methods such as plating and a sol-gel method. Among them, the vapor deposition method is preferable, and a plasma CVD and a sputtering method are particularly preferable. It is considered that, in the vapor deposition method, atoms or molecules which form a film run into, with high energy, the plastic film being the base material, and thus an interaction such as a covalent bond is generated between the atom or molecule and the plastic film to thereby contribute easily to the improvement of the adhesiveness between the plastic film and the barrier laminate.

The silicon compound layer may be provided on either surface of the plastic film, or may be provided on each surface. Usually, the silicon compound layer is provided on a smooth surface of the plastic film by using any of the above-described methods.

The silicon compound layer may contain another element as a subcomponent.

The smoothness of the silicon compound layer is preferably less than 1 nm as an average value in 1 μm square (Ra value), more preferably 0.5 nm or less. The formation of the silicon compound layer is preferably performed in a clean room. The cleanliness is preferably class 10000 or less, more preferably class 1000 or less.

### (First Organic Layer)

In the barrier laminate, the first organic layer is an organic layer formed from a composition containing a polymerizable compound and a silane coupling agent. (Hereinafter, the composition containing the polymerizable compound for producing the organic layer may be referred to as a polymerizable composition). The present inventor have found that the adhesiveness between a plastic film and a barrier laminate can be improved by providing a silicon compound layer in a thickness of 40 nm or less between the organic layer and the plastic film. While not being intended to stick to any particular theory, it is considered that a covalent bond is formed between the silicon compound layer and the first organic layer by the silane coupling agent, and as the result, the adhesiveness with the plastic film adhering closely to the silicon compound layer being a thin film is improved.

(Organic Layer Other than First Organic Layer)

It is sufficient that an organic layer other than the first organic layer is an organic layer formed from a composition containing a polymerizable compound. The organic layer may or may not contain a silane coupling agent. The composition for forming an organic layer other than the first organic layer is preferably configured so as to give high adhesiveness between layers, by performing selection depending on a composition of a layer (for example, an inorganic layer) to which the composition is to be applied. From the viewpoint of ease of the manufacturing, an organic layer other than the first organic layer is preferably formed from the same composition as that of the first organic layer.

### (Silane Coupling Agent)

The silane coupling agent preferably contains a polymerizable group, and in particular, preferably contains a (meth)acrylate group. As a preferable silane coupling agent, a silane coupling agent represented by general formula (1) below can be exemplified.

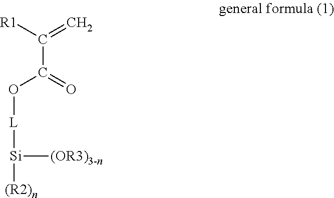

In the formula, R1 each independently represents hydrogen atom or a methyl group, R2 represents a halogen atom or an alkyl group, R3 represents hydrogen atom or an alkyl group, L represents a divalent linking group, and n represents any integer of from 0 to 2.

Examples of the halogen atom include chlorine atom, bromine atom, fluorine atom and iodine atom.

The carbon number of the alkyl group, or an alkyl group in a substituent containing an alkyl group among substituents that will be described later is preferably 1 to 12, more preferably 1 to 9, further more preferably 1 to 6. Specific examples of the alkyl groups include methyl group, ethyl group, a propyl group, a butyl group, a pentyl group and a hexyl group. The alkyl group may be linear or branched, but a linear alkyl group is preferable.

As the divalent linking group, a linking group having 1 to 20 carbon atoms is preferable. Linking groups containing preferably 1 to 12 carbon atoms, more preferably 1 to 6 carbon atoms are acceptable. Examples of the divalent linking groups include an alkylene group (such as ethylene group, 1,2-propylene group, 2,2-propylene group (also referred to as 2,2-propylidene group, 1,1-dimethyl-methylene group), 1,3-propylene group, 2,2-dimethyl-1,3-propylene group, 2-butyl-2-ethyl-1,3-propylene group, 1,6-hexylene group, 1,9-nonylene group, 1,12-dodecylene group, and 1,16-hexadecylene group), an arylene group (such as a phenylene group and a naphthylene group), an ether group, an imino group, a carbonyl group, a sulfonyl group, and divalent residues obtained by binding linearly a plurality of these divalent groups (such as polyethyleneoxyethylene group, polypropyleneoxypropylene group, and 2,2-propylenephenylene group). These groups may have a substituent. Furthermore, the divalent linking group may be a linking group obtained by binding linearly two or more among these groups in plural number. Among them, an alkylene group, an arylene group and a divalent group obtained by binding linearly these in plural number are preferable, and an unsubstituted alkylene group, an unsubstituted arylene group and a divalent group obtained by binding linearly these groups in plural number are more preferable. The substituent includes an alkyl group, an alkoxy group, an aryl group, an aryloxy group or the like.

The silane coupling agent is contained preferably in 1 to 30% by mass, more preferably in 5 to 20% by mass relative to the solid content of the polymerizable composition.

Moreover, in the present invention, two or more kinds of silane coupling agents may be contained, and, in that case, the total content thereof is within the above range.

Specific examples of the silane coupling agents used preferably in the present invention are shown below, but the present invention is not limited to these.

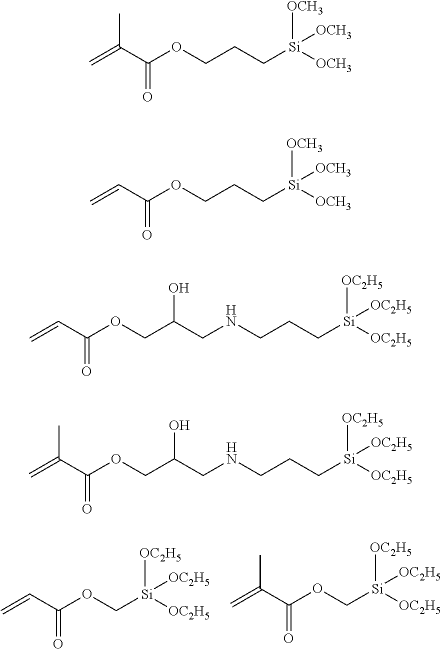 [SMILES: C=C(C)C(=O)OCCC[Si](OC)(OC)OC ; C=CC(=O)OCCC[Si](OC)(OC)OC ; C=CC(=O)OCC(O)CNCCC[Si](OCC)(OCC)OCC ; C=C(C)C(=O)OCC(O)CNCCC[Si](OCC)(OCC)OCC ; C=CC(=O)OC[Si](OCC)(OCC)OCC ; C=C(C)C(=O)OC[Si](OCC)(OCC)OCC]

### (Polymerizable Compound)

The polymerizable compound is a compound having a polymerizable group, and, when the silane coupling agent has a polymerizable group, the silane coupling agent is also included in the polymerizable compound. Two or more kinds of the polymerizable compound may be contained in the composition for forming the organic layer in the gas barrier film. The polymerizable compound is preferably a compound having an ethylenically unsaturated bond at a terminal or on a side chain, and/or a compound having epoxy or oxetane at a terminal or on a side chain. Among these described above, a compound having an ethylenically unsaturated bond at a terminal or on a side chain is preferable. Examples of the compounds each having an ethylenically unsaturated bond at a terminal or on a side chain include (meth)acrylate-based compounds, acrylamide-based compounds, styrene-based compounds, maleic anhydride and the like, and (meth)acrylate-based compounds are preferable.

As the (meth)acrylate-based compound, (meth)acrylate, urethane(meth)acrylate, polyester(meth)acrylate, epoxy (meth)acrylate and the like are preferable.

Hereinafter, specific examples of the (meth)acrylate-based compounds are shown, but the present invention is not limited to these.

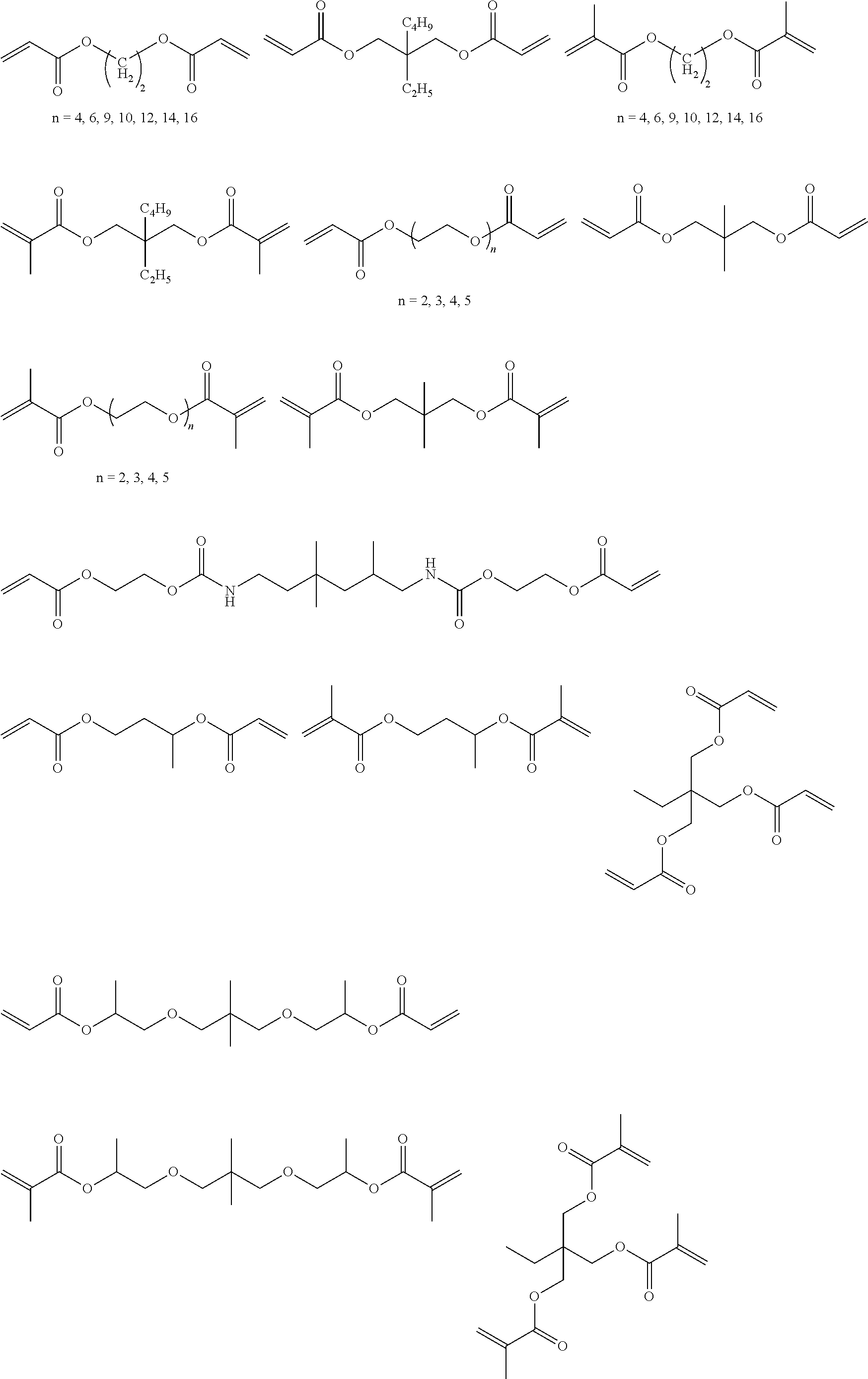

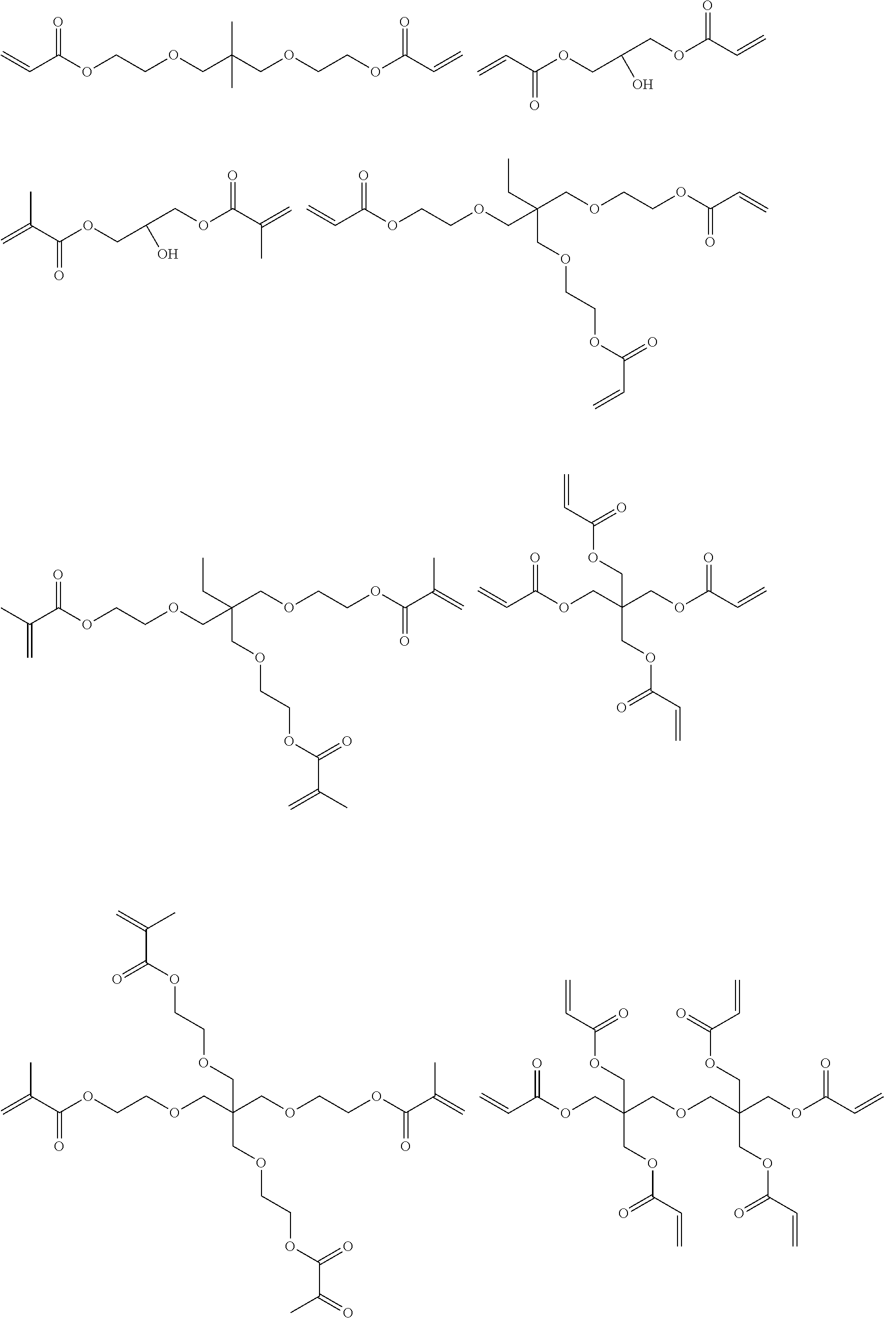

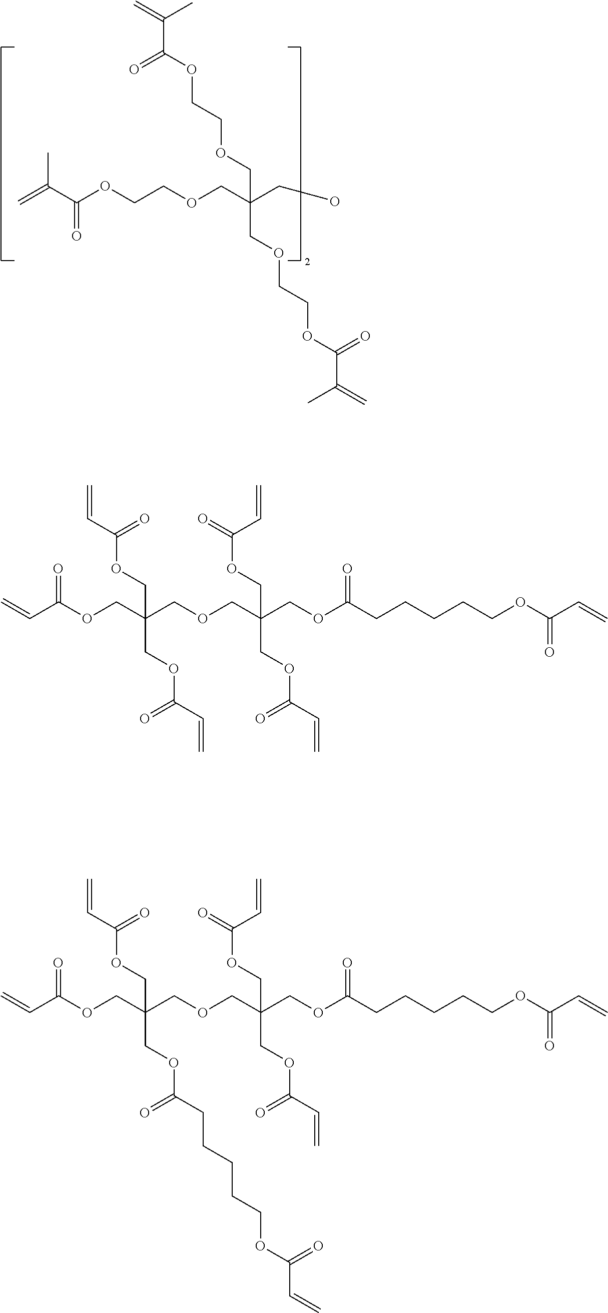

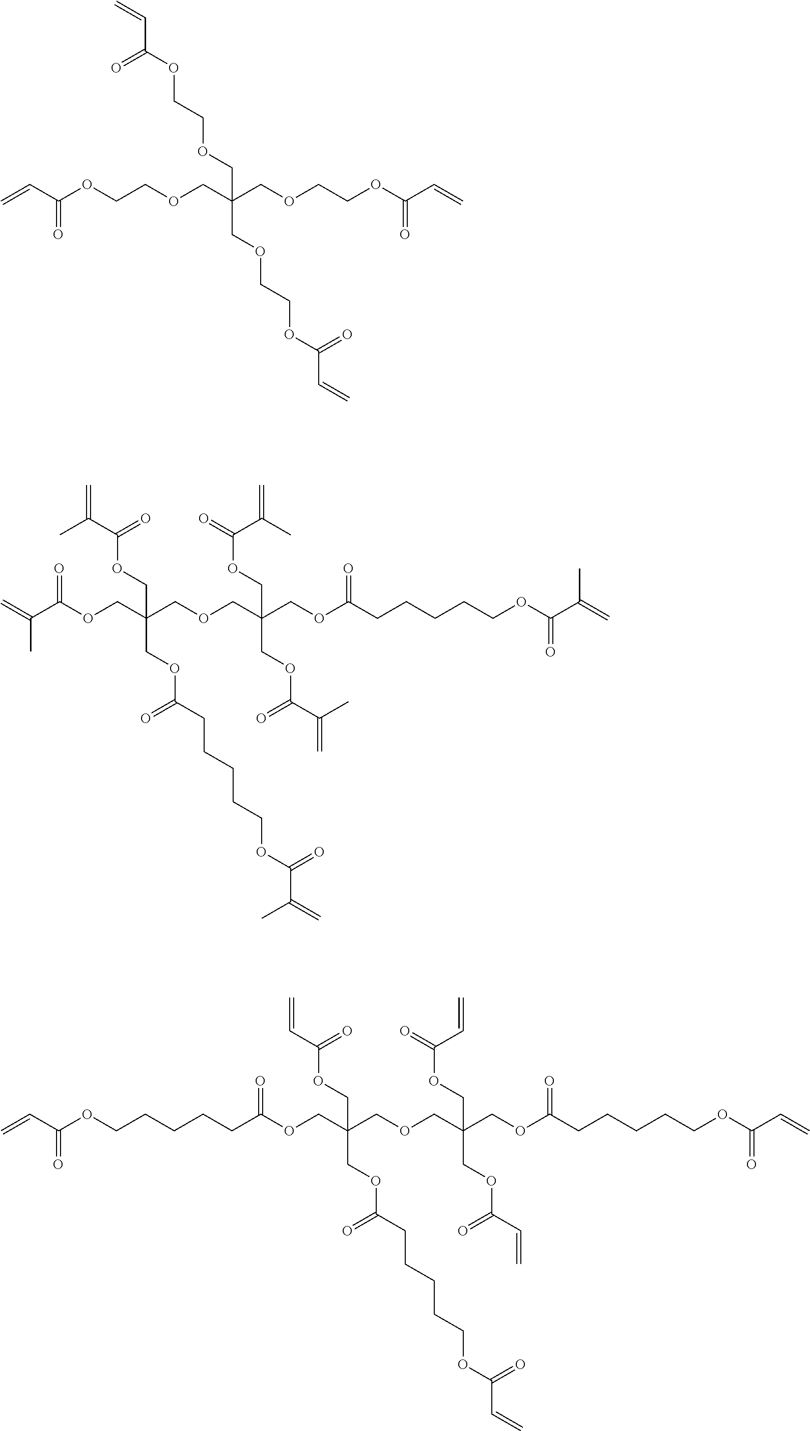

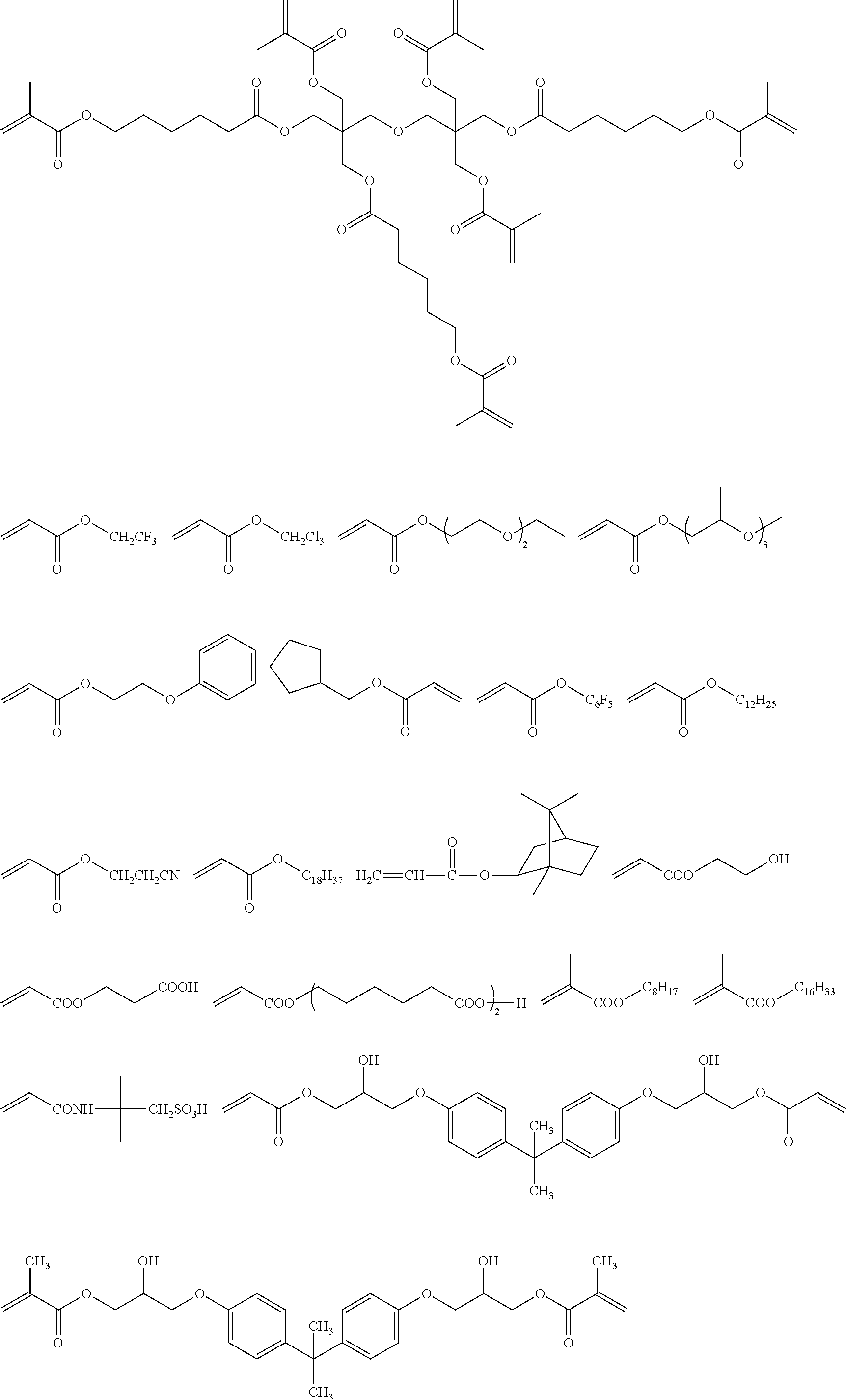

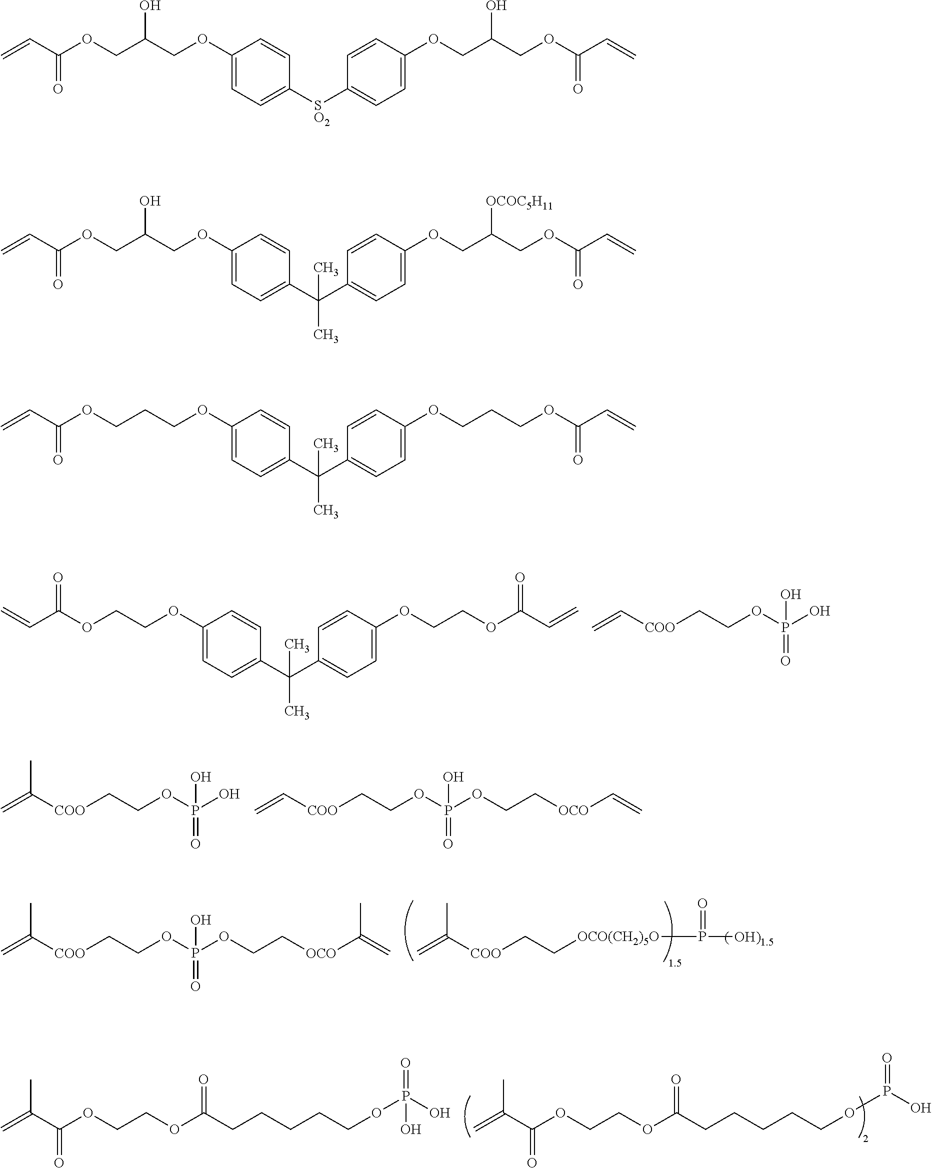

Furthermore, a methacrylate-based compound represented by a general formula (2) below can also be used preferably.

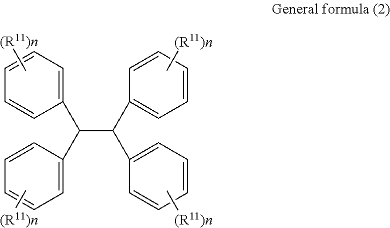

In general formula (2), R¹¹ represents a substituent, and each may be the same or different. n represents an integer of 0 to 5, and each may be the same or different. However, at least one R¹¹ contains a polymerizable group.

R¹¹ as a substituent includes groups formed of a combination of a polymerizable group and one or more of —CR¹²₂— (R¹² is hydrogen atom or a substituent), —CO—, —O—, a phenylene group, —S—, —C≡C—, —NR¹³— (R¹³ is hydrogen atom or a substituent) and —CR¹⁴═CR¹⁵— (R¹⁴, R¹⁵ each is hydrogen atom or a substituent); and among them, a group formed of a combination of a polymerizable group and one or more of —CR¹²₂— (R¹² is hydrogen atom or a substituent), —CO—, —O— and a phenylene group is preferable.

R¹² is hydrogen atom or a substituent, and is preferably hydrogen atom or hydroxy group.

At least one R¹¹ preferably contains hydroxy group. By containing hydroxy group, a curing ratio of the organic layer is improved.

At least one R¹¹ has molecular weight of preferably 10 to 250, more preferably 70 to 150.

As to a position at which R¹¹ is bonded, the R¹¹ is preferably bonded at least at a para position.

n represents an integer of 0 to 5, is preferably an integer of 0 to 2, more preferably 0 or 1, and furthermore preferably every n is 1.

In the compound represented by general formula (2), preferably at least two among R¹¹s have the same structure. In addition, more preferably each n is 1 and at least every two among four R¹¹s have the same structure, further more preferably each n is 1 and four R¹¹s have the same structure. The polymerizable group belonging to general formula (2) is preferably (meth)acryloyl group or epoxy group, more preferably (meth)acryloyl group. The number of the polymerizable group belonging to general formula (2) is preferably two or more, more preferably three or more. Furthermore, although the upper limit thereof is not particularly limited, it is preferably eight or less, more preferably six or less.

The molecular weight of the compound represented by general formula (2) is preferably 600 to 1400, more preferably 800 to 1200.

Hereinafter, specific examples of the compounds represented by general formula (2) are shown, but the present invention is not limited by these. Furthermore, in the compounds below, the case where each of four n's in general formula (2) is 1 is exemplified, but compounds in which one or two or three among four n's in general formula (2) is 0 (for example, a bifunctional, trifunctional compound, or the like), and compounds in which one or two or three or more among four n's in general formula (2) are two or more (compounds in which two or more R¹¹s are bonded to one ring, for example, a pentafunctional, hexafunctional compound, or the like) are also exemplified as preferable compounds.

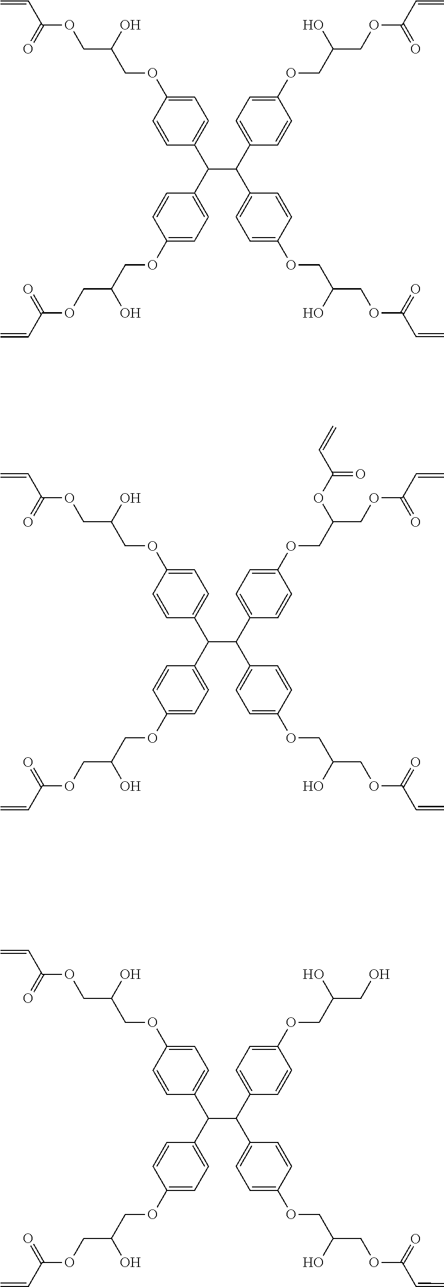

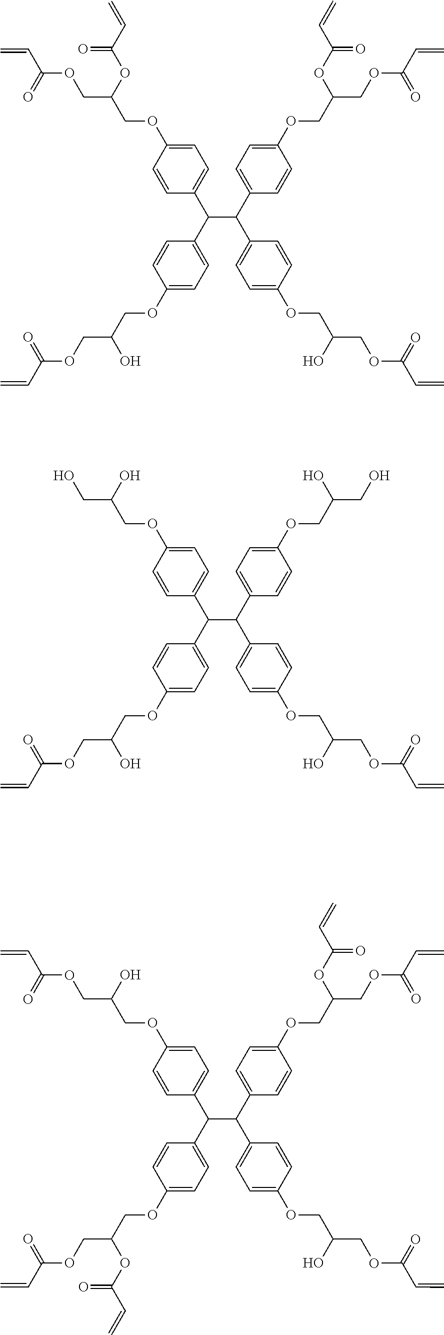

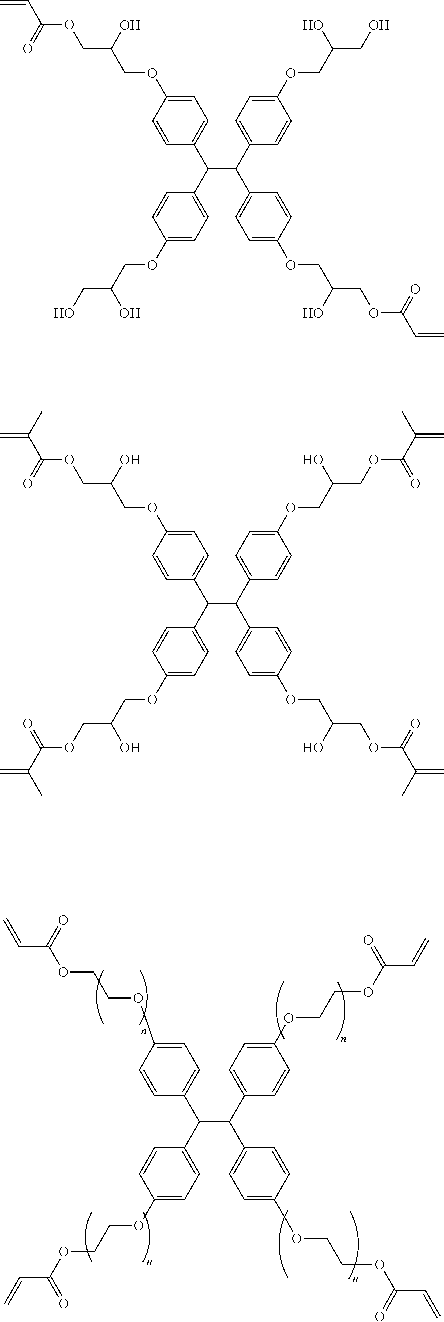

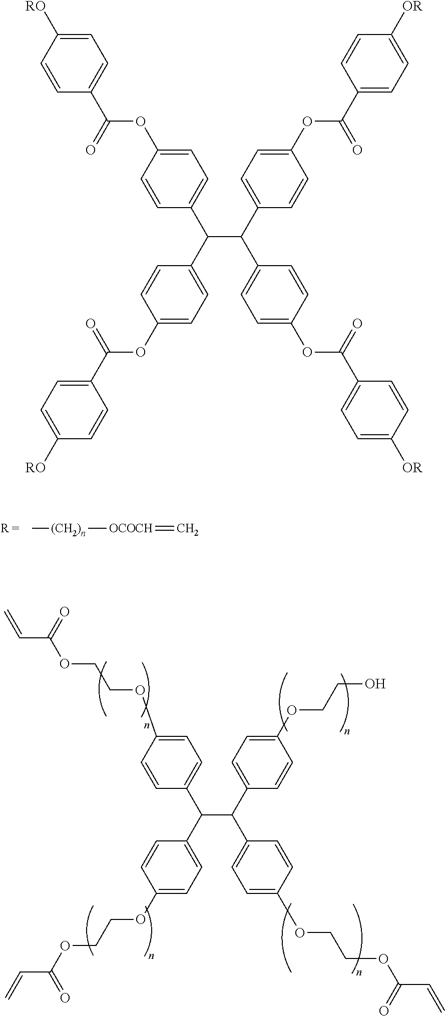

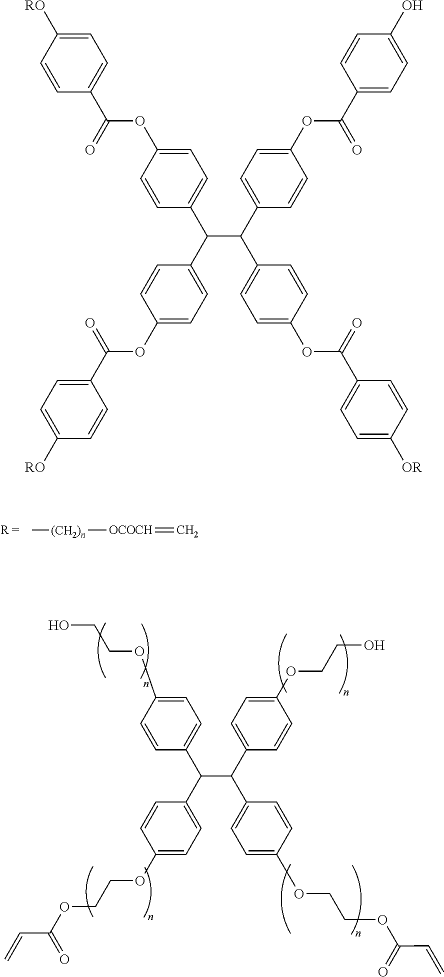

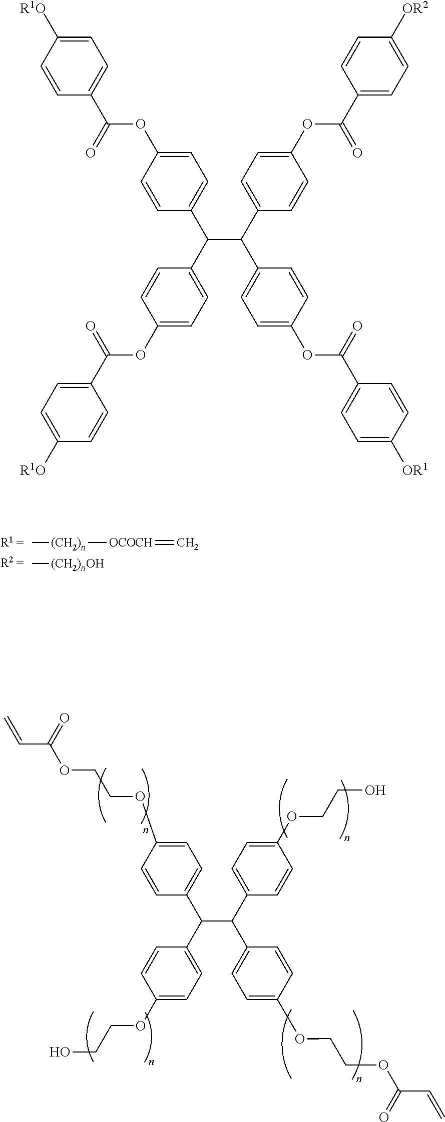

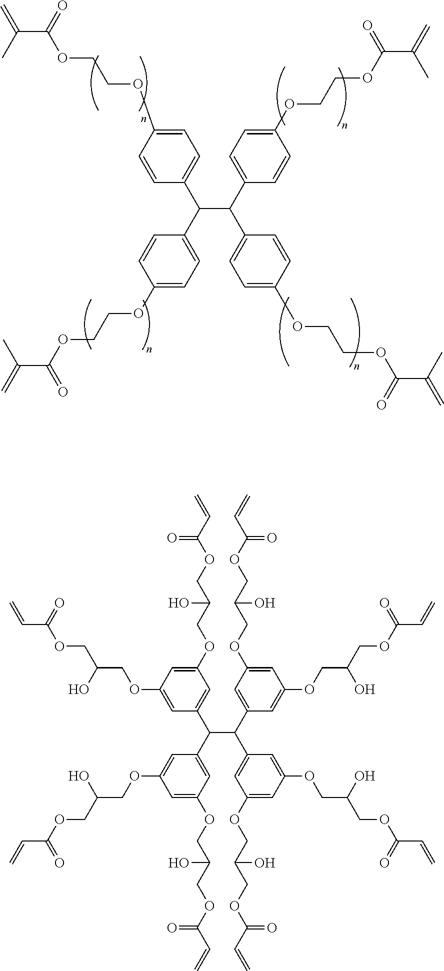

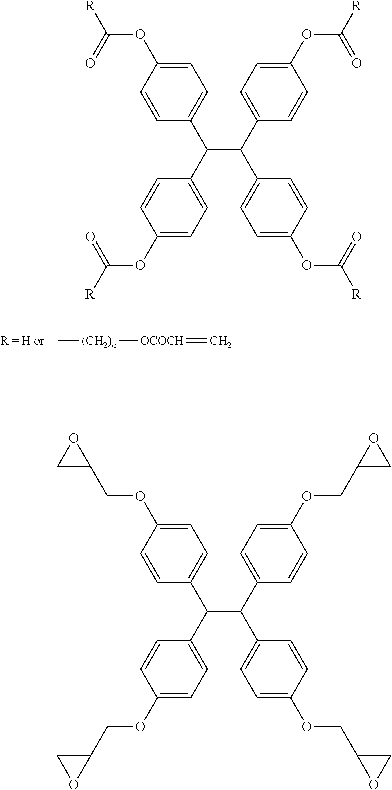

The compound represented by general formula (2) can be commercially available. Furthermore, the compound can also be synthesized by a known method. For example, epoxy acrylate can be obtained by a reaction between an epoxy compound and acrylic acid. In the reaction, usually, these compounds generate bifunctional, trifunctional or pentafunctional compounds or isomers thereof. When separation of these isomers is needed, they can be separated with column chromatography, but in the present invention, they can also be used as a mixture.

The polymerizable compound is contained preferably in 90% by mass or more, and more preferably in 99% by mass or more relative to the solid content of the polymerizable composition.

### (Polymerization Initiator)

The composition containing the polymerizable compound and the silane coupling agent usually contains a polymerization initiator. When the polymerization initiator is used, the content thereof is preferably 0.1% or more by mol and more preferably 0.5 to 2% by mol of the total amount of compounds involved in the polymerization. By setting the composition as described above, the polymerization reaction going through an active component generation reaction can be controlled appropriately. Examples of the photo polymerization initiators include Irgacure series (such as Irgacure651, Irgacure754, Irgacure184, Irgacure2959, Irgacure907, Irgacure369, Irgacure379, and Irgacure819), Darocure series (such as DarocureTPO and Darocure1173), Quantacure PDO which are commercially available from BAFS Japan, Esacure series (such as EsacureTZM, EsacureTZT, and EsacureKTO46) which are commercially available from Lamberti, and the like.

### (Solvent)

The polymerizable composition of the present invention usually contains a solvent. As the solvent, ketones and ester-based solvents are exemplified, and 2-butanone, propylene glycol monoethyl ether acetate and cyclohexanone are preferable. The content of the solvent is preferably 60 to 97% by mass and more preferably 70 to 95% by mass of the polymerizable composition.

### (Method for Forming Organic Layer)

As a method for forming the organic layer from the composition containing the polymerizable compound or the like, a method in which the composition is applied onto a silicon compound layer formed on a plastic film, onto an inorganic layer or the like or onto another functional layer, and after that, is cured by light (such as ultraviolet rays), electron beams or heat rays, can be exemplified.

As the method for application, a dip coating method, an air knife coating method, a curtain coating method, a roller coating method, a wire bar coating method, a gravure coating method, a slide coating method or an extrusion coating method using a hopper described in U.S. Pat. No. 2,681,294 can be adopted.

The composition containing the polymerizable compound or the like is preferably cured by light. The irradiation light is usually ultraviolet rays from a high-pressure mercury lamp or a low-pressure mercury lamp. Irradiation energy is preferably 0.1 J/cm² or more, more preferably 0.5 J/cm² or more. When a (meth)acrylate-based compound is used as a polymerizable compound, an oxygen concentration or oxygen partial pressure in the polymerization is preferably set to be low since the compound suffers polymerization inhibition by oxygen in the air. In reducing the oxygen concentration at the time of the polymerization by a nitrogen substitution method, the oxygen concentration is preferably 2% or less, more preferably 0.5% or less. When the oxygen partial pressure in the polymerization is to be reduced by an evacuation method, the total pressure is preferably 1000 Pa or less, more preferably 100 Pa or less. In addition, it is particularly preferable to carry out ultraviolet polymerization by the irradiation with energy of 0.5 J/cm² or more under a reduced pressure condition of 100 Pa or less.

The organic layer in the present invention preferably is smooth and has high film hardness. The smoothness of the organic layer is preferably less than 1 nm and more preferably less than 0.5 nm as an average roughness in 1 μm square (Ra value). A polymerization ratio of the monomer is preferably 85% or more, more preferably 88% or more, further more preferably 90% or more, and particularly preferably 92% or more. The polymerization ratio denoted here means a ratio of reacted polymerizable groups among all the polymerizable groups (such as acryloyl group and methacryloyl group) in the monomer mixture. The polymerization ratio can be determined quantitatively by an infrared absorption method.

The thickness of the organic layer is not particularly limited. However, when the thickness is too small, it becomes difficult to obtain evenness in the thickness, and when thickness is too large, a crack is generated by external force to thereby reduce the barrier property. From the viewpoint, the thickness of the organic layer is preferably 50 nm to 5000 nm, more preferably 200 nm to 4000 nm, and further more preferably 300 nm to 3000 nm.

A foreign substance such as a particle or a projection is preferably absent on the surface of the organic layer. Therefore, the formation of the organic layer is preferably carried out in a clean room. The cleanliness is preferably class 10000 or less, more preferably class 1000 or less.

As to the hardness of the organic layer, higher hardness is preferable. It is known that the inorganic layer is formed smoothly when the organic layer has high hardness and as the result, the barrier performance is improved. The hardness of the organic layer can be represented as microhardness based on a nano indentation method. The microhardness of the organic layer is preferably 100 N/mm or more, more preferably 150 N/mm or more.

### (Inorganic Layer)

The inorganic layer is a layer in the barrier laminate, and is usually a layer of thin film including a metal compound. As a method for forming the inorganic layer, any method can be employed as long as the method is a method that can form an intended thin film. Examples thereof include physical vapor deposition methods (PVD) such as an evaporation method, a sputtering method and an ion implanting method, various chemical vapor deposition methods (CVD), and liquid-phase growth methods such as plating and a sol-gel method, and a plasma CVD method is preferable. Components contained in the inorganic layer are not particularly limited as long as the components satisfy the above-described performance. The examples of the components include, metal oxide, metal nitride, metal carbide, metal oxynitride and metal oxycarbonate; and oxide, nitride, carbide, oxynitride, oxycarbonate or the like containing one or more metals selected from Si, Al, In, Sn, Zn, Ti, Cu, Ce and Ta can be used preferably. Among them, oxide, nitride or oxynitride of a metal selected from Si, Al, In, Sn, Zn and Ti is preferable, and, in particular, metal oxide or nitride of Si or Al is preferable. These may contain another element as a subcomponent.

The smoothness of the inorganic layer is preferably less than 1 nm as an average value in 1 μm square (Ra value), more preferably less than 0.5 nm. The formation of the inorganic layer is preferably performed in a clean room. The cleanliness is preferably class 10000 or less, more preferably class 1000 or less.

The thickness of the inorganic layer is not particularly limited, but is preferably 10 to 200 nm per one layer. For guaranteeing a higher barrier performance, the thickness of the inorganic layer is preferably 20 nm or more. The thickness of the inorganic layer may exceed 20 nm, and can be 30 nm or more, or 40 nm or more. In addition, the thickness of the inorganic layer may be 100 nm or less, 50 nm or less, or 35 nm or less. The inorganic layer may have a larger thickness than the silicon compound layer. This is because the first organic layer is usually deformed easily as compared with the plastic film, and thus the adhesiveness is not reduced easily even when the inorganic layer is thick to generate large stress. When the inorganic layer has a thickness larger than the silicon compound layer, the difference between thicknesses of the inorganic layer and the silicon compound layer can be 5 nm or more, 10 nm or more, or 20 nm or more.

The inorganic layer may have a laminated structure including a plurality of sublayers. In this case, the respective sublayers may have the same composition or different compositions.

### (Lamination of Organic Layer and Inorganic Layer)

The lamination of the organic layer and the inorganic layer can be performed by forming sequentially and repeatedly the organic layer and the inorganic layer depending on an intended layer configuration.

### (Functional Layer)

In the device of the present invention, a functional layer may be included on the barrier laminate or in another position. The functional layer is described in detail in paragraphs 0036 to 0038 of Japanese Patent Application Laid-Open No. 2006-289627. Examples of the functional layers other than these functional layers include a matting agent layer, a protective layer, a solvent-resistant layer, an antistatic layer, a flattening layer, an adhesiveness-improving layer, a light-shielding layer, an antireflection layer, a hard coat layer, a stress-relaxing layer, an antifogging layer, an antifouling layer, a layer to be printed, an easily adhesive layer, and the like.

### (Plastic Film)

The plastic film is not limited in terms of a material, thickness or the like as long as it is a film that can hold the barrier laminate, and can be selected appropriately depending on the intended use or the like. Specifically, the plastic film includes thermoplastic resins such as polyester resin, methacrylic resin, methacrylic acid-maleic acid copolymer, polystyrene resin, transparent fluorine-containing resin, polyimide, fluorinated polyimide resin, polyamide resin, polyamide-imide resin, polyetherimide resin, cellulose acylate resin, polyurethane resin, polyether ether ketone resin, polycarbonate resin, alicyclic polyolefin resin, polyarylate resin, polyether sulfone resin, polysulfone resin, cycloolefin copolymer, fluorine ring-modified polycarbonate resin, alicyclic-modified polycarbonate resin, fluorene ring-modified polyester resin and acryloyl compound. The plastic film is preferably formed of polyester resin, and, as the polyester resin, polyethylene terephthalate (PET) or polyethylene naphthalate (PEN) is more preferable.

The thickness of the plastic film may be selected according to the application of the gas barrier film and is not particularly limited, but the thickness may be usually 1 to 800 μm, is preferably 10 to 200 μm, and is more preferably 50 to 150 μm.

When the gas barrier film of the present invention is to be used as a substrate for a device such as an organic EL element to be described later, the plastic film is preferably made of a raw material having heat-resisting properties. Specifically, the plastic film is preferably formed of a raw material having high heat-resisting properties of the glass transition temperature (Tg) of 100° C. or higher and/or a linear thermal expansion coefficient of 40 ppm/° C. or less, and having transparency. Tg and a linear thermal expansion coefficient can be adjusted through the use of an additive or the like. Examples of the thermoplastic resins include polyethylene naphthalate (PEN: 120° C.), polycarbonate (PC: 140° C.), alicyclic polyolefin (such as ZEONOR1600: 160° C., manufactured by ZEON CORPORATION), polyarylate (PAr: 210° C.), polyether sulfone (PES: 220° C.), polysulfone (PSF: 190° C.), cycloolefin copolymer (COC: compound in Japanese Patent Application Laid-Open No. 2001-150584: 162° C.), polyimide (such as NEOPRIME manufactured by Mitsubishi Gas Chemical Co., Inc.: 260° C.), fluorene ring-modified polycarbonate (BCF-PC: compound in Japanese Patent Application Laid-Open No. 2000-227603: 225° C.), alicyclic-modified polycarbonate (IP-PC: compound in Japanese Patent Application Laid-Open No. 2000-227603: 205° C.), acryloyl compound (compound in Japanese Patent Application Laid-Open No. 2002-80616: 300° C. or higher) (temperature in the parentheses shows Tg). In particular, when transparency is required, the use of alicyclic polyolefin or the like is preferable.

### (Application of Gas Barrier Film)

The gas barrier film of the present invention can be used for sealing a device that requires barrier properties, and can also be applied to an optical member.

The gas barrier film can also be used as a film substrate having a barrier layer having a function of shielding oxygen, moisture, nitrogen oxide, sulfur oxide, ozone, and the like in the air. The film substrate is preferably used for sealing an element that is possibly deteriorated by water, oxygen or the like with the lapse of time by the use even under normal temperature and pressure. Examples thereof include an organic EL element, a liquid crystal display element, a solar cell, a touch panel, and the like.

The gas barrier film of the present invention can be used as a substrate of a device and as a film for sealing by a solid sealing method. The solid sealing method is a method in which a protective film is formed on a device, and after that, an adhesive layer and a gas barrier film is laminated and cured. The adhesive agent is not particularly limited, and thermally curable epoxy resin, photo-curable acrylate resin, and the like are exemplified.

### (Device)

The gas barrier film of the present invention is used preferably for devices in which the performance is deteriorated by a chemical component in the air (such as oxygen, water, nitrogen oxide, sulfur oxide or ozone). Examples of the devices include electronic devices such as an organic EL element, a liquid crystal display element, a thin film transistor, a touch panel, electronic paper and a solar cell, and the gas barrier film can be used preferably for an organic EL element.

An example of an organic EL element using a gas barrier film is described in detail in Japanese Patent Application Laid-Open No. 2007-30387.

As a liquid crystal display element, the description in paragraph 0044 in Japanese Patent Application Laid-Open No. 2009-172993 can be referred to.

Additional application examples thereof include a thin film transistor described in Published Japanese translation of PCT patent application No. 10-512104, a touch panel described in Japanese Patent Application Laid-Open No. 5-127822, Japanese Patent Application Laid-Open No. 2002-48913 or the like, electronic paper described in Japanese Patent Application Laid-Open No. 2000-98326, a solar cell described in Japanese Patent Application No. 7-160334, and the like.

### (Optical Member)

Examples of the optical members using the gas barrier film of the present invention include a circularly polarizing plate and the like.

The circularly polarizing plate can be produced by laminating a λ/4 plate and a polarizing plate while using the gas barrier film of the present invention as a substrate. In this case, these are laminated so that the slow axis of the λ/4 plate and the absorption axis of the polarizing plate gives 45°. As the polarizing plate, the use of one drawn in the direction of 45° relative to a longitudinal direction (MD) is preferable, and for example, one described in Japanese Patent Application Laid-Open No. 2002-865554 can be used preferably.

### EXAMPLES

Hereinafter, the present invention will be described more specifically through Example. Materials, amounts used, percentages, treatment contents, treatment procedures and the like shown in Example below can be changed appropriately as long as they do not depart from the gist of the present invention. Accordingly, the scope of the present invention is not limited to specific examples shown below.

### [Production of Gas Barrier Film Substrate]

A gas barrier film substrate having a configuration shown in Table 2 was produced as follows.

On a smooth surface of a polyethylene naphthalate film (Teonex Q65FA, thickness 100 μm, manufactured by Teijin DuPont), a silicon compound layer was produced by a vacuum film formation. A plasma CVD method was selected for forming a layer of silicon nitride, and a vacuum evaporation method was selected for forming a layer of silicon oxide. Onto the surface of the silicon compound layer, a polymerizable composition containing 50 g of a polymerizable compound (acrylate 1 or acrylate 2), 1 g of a polymerization initiator (Esacure KTO46, by Lamberti), 5 g of a silane coupling agent ((KBM-5013, manufactured by Shin-Etsu Silicone) or (KBM-503, manufactured by Shin-Etsu Silicone)) and 400 g of 2-butanone was coated for the formation of a film so as to give a dry thickness of 1000 nm, which was irradiated and cured with ultraviolet rays having irradiation amount of 0.5 J/cm² under a nitrogen atmosphere with oxygen content of 100 ppm or less, and thus an organic layer was produced. On the surface of the organic layer, an inorganic layer was produced so as to give a thickness of 50 nm by a vacuum film-forming method. A plasma CVD method was selected for production of silicon nitride, and a sputtering method was selected for the production of aluminum oxide.

As to the gas barrier film substrate obtained, adhesiveness was measured by a technique below.

### [Adhesiveness Test]

In order to evaluate the adhesiveness of a barrier laminate including a silicon compound layer, an organic layer and an inorganic layer on a PEN base material, a cross-cut adhesion test in conformity with JIS K5400 was performed. Each cut at 90° relative to the layer was made with a cutter knife, on the surface of the gas barrier film substrate having the layer configuration, at intervals of 1 mm, and 100 grids at intervals of 1 mm were produced. On this, a Mylar tape having a width of 2 cm [polyester tape (No. 31B), manufactured by Nitto Denko Corporation] was stuck, and the stuck tape was peeled off using a tape peel test machine. The number of squares (n) remaining without being peeled off among 100 grids on the laminated film was counted. The result is shown under the determination standard shown in a table below.

TABLE 1

| Adhesiveness evaluation | Number of remaining grids |
|---|---|
| A | 96 to 100 |
| B | 91 to 95 |
| C | 81 to 90 |
| D | 80 or less |

### [Measuring Method of Thickness]

The thickness of the silicon compound layer was measured as follows.

From a 100,000 times TEM photograph, the distance between the upper end and lower end of the silicon compound layer was measured randomly in n=10, and the average distance thereof was defined as the thickness.

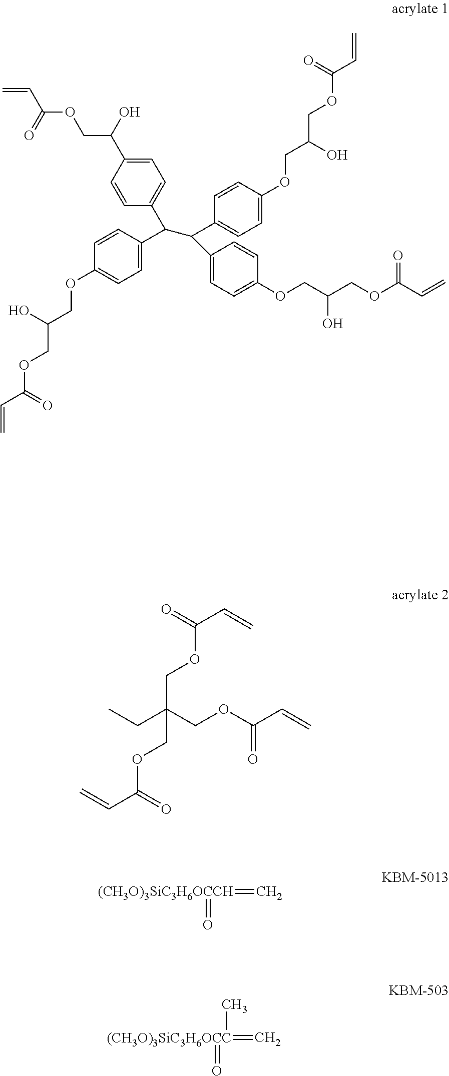

TABLE 2

| | Silicon compound layer | | Organic layer | | Inorganic layer | | |
|---|---|---|---|---|---|---|---|
| | | thickness | Polymerizable | | | thickness | Adhesiveness |
| | Composition | nm | compound | additive | Composition | nm | evaluation |
| Example | SiN | 2 | acrylate 1 | KBM-5013 | SiN | 30 | A |
| Example | SiN | 4 | acrylate 1 | KBM-5013 | SiN | 30 | A |
| Example | SiN | 10 | acrylate 1 | KBM-5013 | SiN | 30 | B |
| Example | SiN | 20 | acrylate 1 | KBM-5013 | SiN | 30 | B |
| Example | SiN | 40 | acrylate 1 | KBM-5013 | SiN | 30 | C |
| Comparative Example | SiN | 40 | acrylate 1 | None | SiN | 30 | D |
| Comparative Example | SiN | 50 | acrylate 1 | KBM-5013 | SiN | 30 | D |
| Example | SiO | 2 | acrylate 1 | KBM-5013 | SiN | 30 | A |
| Example | SiO | 4 | acrylate 1 | KBM-5013 | SiN | 30 | A |
| Example | SiO | 10 | acrylate 1 | KBM-5013 | SiN | 30 | B |
| Example | SiO | 20 | acrylate 1 | KBM-5013 | SiN | 30 | B |
| Example | SiO | 40 | acrylate 1 | KBM-5013 | SiN | 30 | C |
| Example | SiN | 2 | acrylate 2 | KBM-5013 | SiN | 30 | A |
| Example | SiN | 4 | acrylate 2 | KBM-5013 | SiN | 30 | A |
| Example | SiN | 10 | acrylate 2 | KBM-5013 | SiN | 30 | B |
| Example | SiN | 20 | acrylate 2 | KBM-5013 | SiN | 30 | B |
| Example | SiN | 40 | acrylate 2 | KBM-5013 | SiN | 30 | C |
| Example | SiN | 2 | acrylate 1 | KBM-503 | SiN | 30 | A |
| Example | SiN | 4 | acrylate 1 | KBM-503 | SiN | 30 | A |
| Example | SiN | 10 | acrylate 1 | KBM-503 | SiN | 30 | B |
| Example | SiN | 20 | acrylate 1 | KBM-503 | SiN | 30 | B |
| Example | SiN | 40 | acrylate 1 | KBM-503 | SiN | 30 | C |
| Example | SiN | 2 | acrylate 1 | KBM-5013 | AlO | 30 | A |
| Example | SiN | 4 | acrylate 1 | KBM-5013 | AlO | 30 | A |
| Example | SiN | 10 | acrylate 1 | KBM-5013 | AlO | 30 | B |
| Example | SiN | 20 | acrylate 1 | KBM-5013 | AlO | 30 | B |
| Example | SiN | 40 | acrylate 1 | KBM-5013 | AlO | 30 | C |
| Comparative Example | | — | acrylate 1 | KBM-5013 | SiN | 30 | D |
| Comparative Example | | — | acrylate 1 | None | SiN | 30 | D |

While the present invention has been described in detail and with reference to specific embodiments thereof, it will be apparent to one skilled in the art that various changes and modifications can be made therein without departing from the spirit and scope thereof. All the publications referred to in the present specification are expressly incorporated herein by reference in their entirety. The foregoing description of preferred embodiments of the invention has been presented for purposes of illustration and description, and is not intended to be exhaustive or to limit the invention to the precise form disclosed. The description was selected to best explain the principles of the invention and their practical application to enable others skilled in the art to best utilize the invention in various embodiments and various modifications as are suited to the particular use contemplated. It is intended that the scope of the invention not be limited by the specification, but be defined claims set forth below.

1. A gas barrier film comprising a plastic film, an organic layer and an inorganic layer in this order, the gas barrier film having a silicon compound layer comprising one or more compounds selected from the group consisting of silicon oxide, silicon nitride and silicon carbide between the plastic film and the organic layer; the plastic film and the silicon compound layer, and the silicon compound layer and the organic layer being directly in contact to each other respectively; the thickness of the silicon compound layer being 40 nm or less; the organic layer being a layer formed of a composition containing a polymerizable compound and a silane coupling agent; and the thickness of the inorganic layer being larger than the thickness of the silicon compound layer.

2. The gas barrier film according to claim 1, wherein the difference between thicknesses of the inorganic layer and the silicon compound layer is 10 nm or more.

3. The gas barrier film according to claim 1, wherein the difference between thicknesses of the inorganic layer and the silicon compound layer is 20 nm or more.

4. The gas barrier film according to claim 1, wherein the thickness of the silicon compound layer is 20 nm or less.

5. The gas barrier film according to claim 2, wherein the thickness of the silicon compound layer is 20 nm or less.

6. The gas barrier film according to claim 3, wherein the thickness of the silicon compound layer is 20 nm or less.

7. The gas barrier film according to claim 1, wherein the thickness of the silicon compound layer is less than 5 nm.

8. The gas barrier film according to claim 2, wherein the thickness of the silicon compound layer is less than 5 nm.

9. The gas barrier film according to claim 3, wherein the thickness of the silicon compound layer is less than 5 nm.

10. The gas barrier film according to claim 1, wherein the thickness of the silicon compound layer is 10 nm or less and the thickness of the inorganic layer is 20 nm or more.

11. The gas barrier film according to claim 1, wherein the thickness of the plastic film is 10 μm to 200 μm and the thickness of the organic layer is 50 nm to 5000 nm.

12. The gas barrier film according to claim 2, wherein the thickness of the plastic film is 10 μm to 200 μm and the thickness of the organic layer is 50 nm to 5000 nm.

13. The gas barrier film according to claim 5, wherein the thickness of the plastic film is 10 μm to 200 μm and the thickness of the organic layer is 50 nm to 5000 nm.

14. The gas barrier film according to claim 10, wherein the thickness of the plastic film is 10 μm to 200 μm and the thickness of the organic layer is 50 nm to 5000 nm.

15. The gas barrier film according to claim 1, wherein the inorganic layer comprises silicon nitride or aluminum oxide.

16. The gas barrier film according to claim 1, wherein the silane coupling agent is a compound represented by general formula (1): 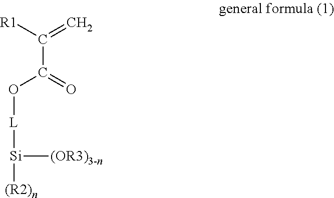
in the formula, R1 each independently represents hydrogen atom or methyl group, R2 represents a halogen atom or an alkyl group, R3 represents hydrogen atom or an alkyl group, L represents a divalent linking group, and n represents any integer of 0 to 2.

17. The gas barrier film according to claim 1, wherein the polymerizable compound is (meth)acrylate.

18. The gas barrier film according to claim 1, wherein the silicon compound layer is a layer produced by a vapor deposition method.

19. The gas barrier film according to claim 1, wherein the inorganic layer is a layer produced by a vapor deposition method.

20. A method of manufacturing a gas barrier film, the method comprising forming an organic layer by applying and curing a composition containing a polymerizable compound onto a plastic film and forming an inorganic layer on the organic layer,
wherein a silicon compound layer comprising one or more compounds selected from the group consisting of silicon oxide, silicon nitride and silicon carbide is formed at a thickness of 40 nm or less by a vapor deposition method, on a surface of the plastic film to which the composition is applied,
the composition comprises a silane coupling agent,
the composition is applied directly onto the silicon compound layer, and the inorganic layer is formed such that the thickness of the inorganic layer being larger than the thickness of the silicon compound layer.
